(19) United States
(12) Patent Application Publication
(10) Pub. No.: US 2017/0084515 A1
(43) Pub. Date: Mar. 23, 2017

(54) Power-Module Device and Power Conversion Device

(71) Applicant: Hitachi, Ltd., Chiyoda-ku, Tokyo (JP)

(72) Inventors: Hiroshi SHINTANI, Tokyo (JP); Eiichi IDE, Tokyo (JP); Atsuo NISHIHARA, Tokyo (JP)

(73) Assignee: Hitachi, Ltd., Chiyoda-ku, Tokyo (JP)

(21) Appl. No.: 15/312,053

(22) PCT Filed: Jun. 20, 2014
(86) PCT No.: PCT/JP2014/066368

§ 371 Date: Nov. 17, 2016

(51) Int. Cl. H01L 23/427; H02M 3/158; H01L 21/48; H01L 25/18; H01L 23/31

(52) U.S. Cl. CPC H01L 23/427; H01L 25/18; H01L 23/3114; H01L 21/4882; H02M 3/158

(57) ABSTRACT

In order to efficiently cool a heat-generating semiconductor element, it is desirable to cool a power semiconductor element from both surfaces. Therefore, in order to cool multiple power semiconductor elements, it is an effective way to alternately arrange a semiconductor component having the incorporated semiconductor element and a cooling device. In addition, it is desirable to eliminate a gap and to reduce contact heat resistance between members in contact with each other, by suitably pressurizing a portion between the semiconductor component having the incorporated semiconductor element and the cooling device. In this case, if rigidity of a case in which the semiconductor component having the incorporated semiconductor element or the cooling device is installed is high in a pressurizing direction, the rigidity hinders a heat transfer point from being suitably pressurized. For these reasons, it is required to provide the case in which the semiconductor component having the incorporated semiconductor element and the cooling device can be alternately arranged, and in which the rigidity in the pressurizing direction is low. A power conversion device for handling a high-power voltage needs to ensure pressure resistance between the semiconductor elements or circuits inside the device. It is an effective way to seal the semiconductor component with a sealing material such as a silicone gel. Therefore, it is necessary to install the semiconductor component or the circuit having the incorporated semiconductor element, in a case from which the liquid silicone gel prior to curing does not leak even if the gel is injected. For these reasons, an object to be achieved by the invention is to provide the power conversion device in which the semiconductor element can be cooled from both surfaces by alternately arranging the semiconductor component having the incorporated semiconductor element and the cooling device, and which includes the case in which the rigidity in the pressurizing direction is low and which can be sealed while leakage is prevented even if the liquid silicone gel is injected. The above-described object can be achieved as follows. A thin plate is formed in a shape having as many recesses as the number of the mounted semiconductor components having the incorporated semiconductor element. Concurrently, a case is disposed so that all edges configuring an outer shape of the thin plate are arranged on substantially the same plane. The semiconductor component having the incorporated semiconductor element is arranged at a position serving as the recess of the case. The cooling devices are arranged so as to interpose the semiconductor component having the incorporated semiconductor element via the case. The semiconductor component having the incorporated semiconductor element is sealed with a silicone gel.

### TECHNICAL FIELD

The present invention relates to a power-module device and a semiconductor element.

### BACKGROUND ART

A power conversion device equipped with a power semiconductor element such as an insulated gate bipolar transistor (IGBT) and a free wheel diode (FWD) is used for various products such as electric vehicles, hybrid vehicles, railways, and electric power equipment. These power semiconductor elements generate heat when operated. Accordingly, it is necessary to suitably cool the power semiconductor elements. Therefore, a water-cooling cooler for circulating water or an air-cooling cooler using a fin is provided, and heat exchange with the cooler is performed, thereby cooling the power semiconductor elements.

Here, a general power conversion device needs multiple semiconductor elements. Furthermore, it is necessary to tightly and densely mount the multiple semiconductor elements on the power conversion device. In order to efficiently cool the multiple semiconductor elements, a structure has been developed which cools a semiconductor component (having the semiconductor element stored therein) from both surfaces. In order to efficiently cool a heat-generating semiconductor element in this way, it is an effective way to alternately arrange the semiconductor component having the incorporated semiconductor element and the cooling device. For example, a technique is known in which the semiconductor component and a cooling tube for cooling are alternately arranged and stacked on each other. For example, this technique is disclosed in JP-A-2011-181687 (PTL 1)

### CITATION LIST

### Patent Literature

PTL 1: JP-A-2011-181687

### SUMMARY OF INVENTION

### Technical Problem

The above-described technique in the related art realizes highly efficient cooling for the semiconductor element by alternately arranging the semiconductor component and the cooling device. However, insulation is simply ensured by a space. Accordingly, in order to perform the cooling, a cooling medium path which connects cooling members to each other is generally used, or a cooling fin thermally connected to the cooling members is used. Moreover, there is a tendency that the arrangement becomes much denser by alternately arranging the semiconductor component and the cooling device. However, the above-described technique in the related art does not take it into account that a portion of the semiconductor component is sealed with a sealing material.

An object of the invention is to provide a power-module device and a power conversion device, which suitably employ a sealing material so as to correspond to high pressure while cooling efficiency is maintained.

### Solution to Problem

According to the invention, in order to achieve the above-described object, there is provided a power-module device configured to cause a cooling member to cool a semiconductor component from both surface sides by alternately arranging the semiconductor component and the cooling member. A plurality of the semiconductor components are provided. The semiconductor component includes a semiconductor element and a terminal connected to the semiconductor element. At least a portion of the semiconductor element performs a switching operation. The semiconductor component has an integral case in which a plate material is molded so as to isolate the semiconductor component and the cooling member from each other. The case has an extension portion for sealing the terminal with a sealing material, and further has a cooling medium path which connects the cooling members to each other, or a cooling fin which is thermally connected to the cooling member.

### Advantageous Effects of Invention

According to the invention, it is possible to provide a power-module device and a power conversion device which are suitable for high pressure while cooling efficiency is maintained.

### BRIEF DESCRIPTION OF DRAWINGS

FIG. 1 is an external view of a semiconductor device according to a first embodiment in the invention.

FIG. 2 is a side view and a sectional view of the semiconductor device according to the first embodiment in the invention.

FIG. 3 is an external view and a sectional view of a semiconductor component having an incorporated semiconductor element, which is a component configuring the semiconductor device according to the first embodiment in the invention.

FIG. 4 is an external view and a sectional view of a heat sink which is a component configuring the semiconductor device according to the first embodiment in the invention.

FIG. 5 is a sectional view of a terminal block which is a component configuring the semiconductor device according to the first embodiment in the invention.

FIG. 6 is an external view and a sectional view of a case which is a component configuring the semiconductor device according to the first embodiment in the invention.

FIG. 7 is a view for describing a method for manufacturing the case which is a component configuring the semiconductor device according to the first embodiment in the invention.

FIG. 8 is a first view illustrating the method for manufacturing the semiconductor device according to the first embodiment in the invention.

FIG. 9 is a second view illustrating the method for manufacturing the semiconductor device according to the first embodiment in the invention.

FIG. 10 is a third view illustrating the method for manufacturing the semiconductor device according to the first embodiment in the invention.

FIG. 11 is a fourth view illustrating the method for manufacturing the semiconductor device according to the first embodiment in the invention.

FIG. 12 is a view illustrating a method for pressurizing the semiconductor device according to the first embodiment in the invention.

FIG. 13 is a view for describing a method for manufacturing a case which is a component configuring a semiconductor device according to a second embodiment in the invention.

FIG. 14 is a view illustrating a method for manufacturing the semiconductor device according to the second embodiment in the invention.

FIG. 15 is a view illustrating a semiconductor device according to a third embodiment in the invention.

FIG. 16 is a view illustrating a semiconductor device according to a fourth embodiment in the invention.

FIG. 17 is a view for describing a heat pipe which is a component configuring the semiconductor device according to the fourth embodiment in the invention.

FIG. 18 is a view illustrating a semiconductor device according to a fifth embodiment in the invention.

FIG. 19 is a view for describing a heat pipe which is a component configuring the semiconductor device according to the fifth embodiment in the invention.

FIG. 20 is an external view and a sectional view of a semiconductor device according to a sixth embodiment in the invention.

FIG. 21 is a view for describing a method for manufacturing a case which is a component configuring the semiconductor device according to the sixth embodiment in the invention.

FIG. 22 is a first view illustrating a method for manufacturing the semiconductor device according to the sixth embodiment in the invention.

FIG. 23 is a second view illustrating a method for manufacturing the semiconductor device according to the sixth embodiment in the invention.

FIG. 24 is a third view illustrating a method for manufacturing the semiconductor device according to the sixth embodiment in the invention.

FIG. 25 is a fourth view illustrating a method for manufacturing the semiconductor device according to the sixth embodiment in the invention.

FIG. 26 is a view illustrating a power conversion device of the semiconductor device according to the first embodiment in the invention.

### DESCRIPTION OF EMBODIMENTS

Hereinafter, embodiments will be described with reference to the drawings.

### Embodiment 1

FIG. 26 illustrates a circuit diagram of a power conversion device according to a first embodiment in the invention. As a semiconductor module, a case 1 stores a semiconductor component 27-1, a semiconductor component 27-2, and a semiconductor component 27-3. In this example, the power conversion device is formed from two sets of the case 1, a condenser 101, and a condenser 102.

The semiconductor components 27-1 (upper side) (S1), 27-2 (upper side) (S2), 27-2 (lower side) (S3), and 27-1 (lower side) (S4) are connected in series between DC terminals +E and −E via an external terminal 3-2 of each case 1 (the semiconductor components 27-1, 27-2, and 27-3 are collectively referred to as a semiconductor component 27. Similarly, “−1”, “−2”, and the like will be given to other components so as to indicate that the components partially form a collectively referred component). Here, the semiconductor components 27-1 and 27-2 are configured to include a parallel circuit of a switching element such as IGBT and a reflux diode (reverse connection). Between the DC terminals +E and −E, the condensers 101 and 102 are connected in series, in parallel with a series circuit of the semiconductor component 27. A neutral terminal N is configured to function as a neutral polarity in a connection point between the condensers 101 and 102. The neutral terminal N and a connection point between the semiconductor components 27-1 (upper side) and 27-2 (upper side) are connected by the semiconductor component 27-3 (upper side) via an external terminal 3-3 disposed in each case 1. Similarly, a connection point between the semiconductor components 27-1 (lower side) and 27-2 (lower side) is connected by the semiconductor component 27-3 (lower side).

The semiconductor component 27-1 is connected to an external terminal 3-1 and an internal terminal 28-2-1 of the semiconductor component 27-2, respectively, via an internal terminal 28-1-1 and an internal terminal 28-1-2. The semiconductor component 27-2 is connected to the internal terminal 28-2-1 of the semiconductor component 27-2 and the external terminal 3-2, respectively, via an internal terminal 28-2-2 and an internal terminal 28-2-2. The semiconductor component 27-3 is connected to a connection point between the internal terminal 28-1-2 of the semiconductor component 27-1 and the internal terminal 28-2-1 of the semiconductor component 27-2, and the external terminal 3-3, respectively, via an internal terminal 28-3-1 and an internal terminal 28-3-2.

The semiconductor component 27-3 is configured to function as a diode. In this configuration, the semiconductor components 27-1 and 27-2 are controlled so as to be turned on/off, thereby selectively outputting any one of a DC voltage +E, a neutral voltage N, and a DC voltage −E between the semiconductor components 27-2 (upper side) and 27-2 (lower side). Alternatively, an alternating current applied between the semiconductor components 27-2 (upper side) and 27-2 (lower side) is output to the DC terminal +E and the DC terminal −E as a direct current. That is, power conversion is performed.

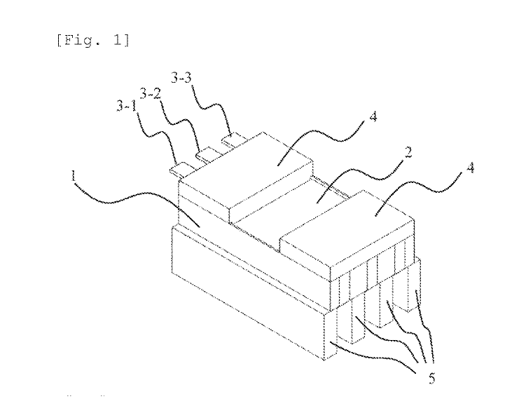

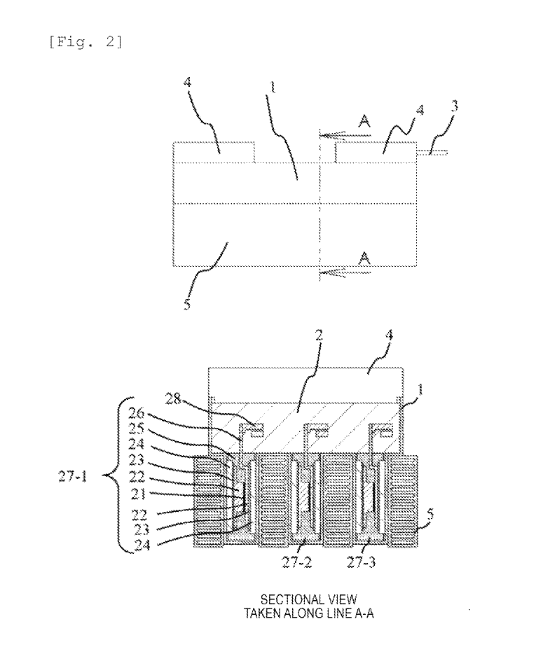

FIG. 1 illustrates an external view of the power conversion device according to the first embodiment in the invention. FIG. 2 illustrates a side view and a sectional view. Four heat sinks 5 are arranged in a lower portion of the case 1, and a terminal block 4 is arranged in an upper portion of the case 1. An external terminal 3 protrudes on a side surface of the terminal block 4. The external terminal 3 enables the power conversion device to be externally and electrically connected so as to function as the power conversion device.

Referring to a sectional view illustrated in FIG. 2, an internal structure of the power conversion device according to the first embodiment in the invention will be described. The case 1 is configured to include a thin metal plate. A cross-sectional shape of the case 1 is a shape in which both side surfaces are higher than the sealing material 2 and three recesses are formed in the central portion. In the present embodiment, the case 1 employs a bending-processed aluminum plate whose thickness is approximately 0.1 mm. The semiconductor components 27 having the incorporated semiconductor element are respectively arranged in the recesses of the case 1. A total of three semiconductor components 27 having the incorporated semiconductor element are provided. Inside each of the semiconductor components 27 having the incorporated semiconductor element, a semiconductor element 21, a metal circuit 22, an insulating material 23, and a heat radiating member 24 are stacked, and all of these members are sealed with a mold resin 25. In addition, a terminal 26 electrically connected to the metal circuit 22 protrudes from the mold resin 25, and is connected to an internal terminal 28 protruding from the terminal block 4. The internal terminal 28 is connected to the external terminal 3 inside the terminal block 4, thereby enabling the semiconductor element 21 to be externally and electrically connected. In the present embodiment, the terminal 26 protruding from the mold resin 25 of the semiconductor component 27 having the incorporated semiconductor element and the internal terminal 28 protruding from the terminal block 4 are firmly joined to each other by means of welding. In addition, the terminal 26 protruding from the mold resin 25 and the internal terminal 28 protruding from the terminal block 4 are sealed with the sealing material 2. In the present embodiment, even in a case where a silicone gel is used as the sealing material 2 or a high pressure-resistant semiconductor element is used, it is possible to ensure sufficient pressure resistance. Four heat sinks 5 are arranged outside the case 1, that is, on a lower side from the case 1 illustrated in a sectional view in FIG. 2, so as to interpose the semiconductor component 27 having the incorporated semiconductor element therebetween via the case 1. The heat sinks are arranged in this way, thereby enabling any semiconductor component 27 having the incorporated semiconductor element to be cooled from both surfaces.

In the power conversion device according to the first embodiment in the invention, the heat sinks 5 are arranged on both surfaces of all of the semiconductor components 27 having the incorporated semiconductor element. Accordingly, it is possible to efficiently cool heat generation inside the semiconductor component 27 having the incorporated semiconductor element. In this case, the semiconductor component 27 having the incorporated semiconductor element and the heat sink 5 face each other via the thin metal case 1. Since there is no intervening member having great heat resistance, it is possible to minimize heat resistance between the semiconductor component 27 having the incorporated semiconductor element and the heat sink 5. Although not illustrated, contact resistance can be further reduced by disposing a low elastic body having high heat conductivity or grease between the semiconductor component 27 having the incorporated semiconductor element and the case 1, and between the case 1 and the heat sink 5. The semiconductor element 21, the semiconductor component 27 having the incorporated semiconductor element, the terminal 26, and the internal terminal 28 are all sealed with the mold resin 25 or the sealing material 2. Even when used for the power conversion device for handling a high voltage, it is possible to ensure sufficient pressure resistance. Furthermore, even in a case where the semiconductor component 27 having the incorporated semiconductor element or the heat sink 5 is thin and a distance is short between the semiconductor component 27 having the incorporated semiconductor element and the terminal 26 which are adjacent to each other, the sufficient pressure resistance can be ensured using a silicone gel. Therefore, a space for the power conversion device can be further miniaturized.

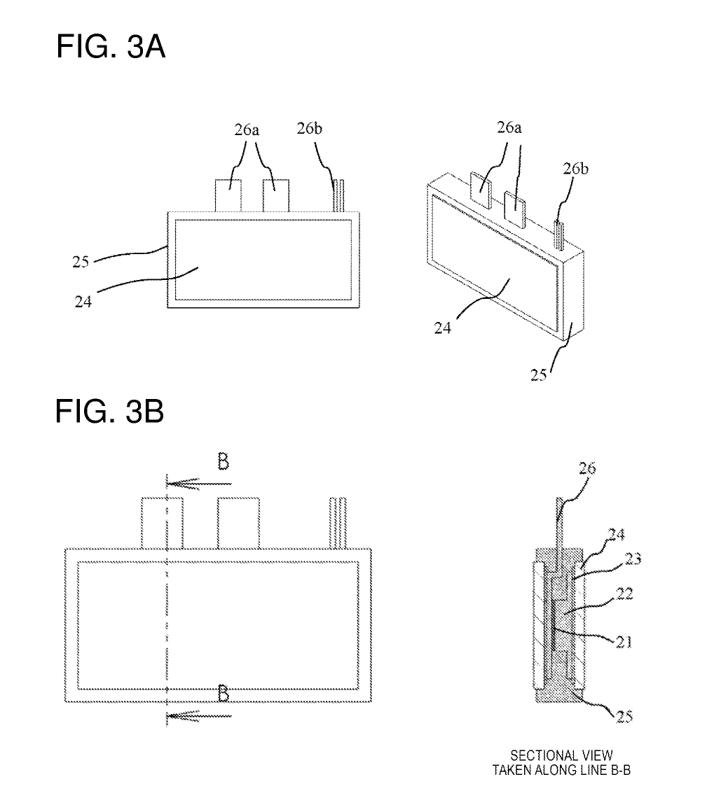

Referring to FIGS. 3 to 6, each member configuring the power conversion device according to the first embodiment in the invention will be described in detail.

FIG. 3a illustrates an external view of the semiconductor component 27 having the incorporated semiconductor element which configures the power conversion device according to the first embodiment in the invention. The semiconductor component 27 having the incorporated semiconductor element which is employed in the present embodiment has a structure in which the heat radiating member 24 is exposed in the central portion on the main surface, terminals 26a and 26b protrude from the upper portion, and all of these are sealed with the mold resin 25. The heat radiating member 24 has a role to transfer heat inside the semiconductor component 27 having the incorporated semiconductor element to the heat sink 5 while being in surface contact with the case 1. The present embodiment employs a highly flat copper-made member. Copper has high heat conductivity, and can further minimize heat resistance between the semiconductor component 27 and the heat sink 5. In the terminals 26a and 26b, a cross section of the terminal 26a which allows a large current to flow therein is increased, thereby decreasing current density. In this manner, it is possible to reduce the Joule heat generated when power is supplied. On the other hand, a cross section of the controlling terminal 26b which does not allow the large current to flow therein is decreased, thereby enabling the conductor component 27 to be miniaturized.

FIG. 3b illustrates a sectional view of the semiconductor component 27 having the incorporated semiconductor element which configures the power conversion device according to the first embodiment in the invention. The semiconductor component 27 has at least one or more semiconductor elements 1. The metal circuit 22 is arranged on both surfaces of the semiconductor element 1, and a portion of the semiconductor component 27 serves as the terminal 26. In the present embodiment, the semiconductor element 1 and the metal circuit 22 are joined to each other by means of soldering. At least one side in the metal circuits 22 arranged on both surfaces of the semiconductor element 1 is configured so that the thickness of the portion in contact with the semiconductor element 1 is greater than the thickness of other portions. In this manner, it is possible to ensure an inter-circuit distance of the metal circuits 22 arranged on both surfaces of the semiconductor element 1. Accordingly, even in a case where a high voltage is handled, reliability can be sufficiently ensured. In the metal circuit 22, the insulating materials 23 are respectively arranged on surfaces opposite to a side facing the semiconductor element 21. The semiconductor element 21 and the metal circuit 22 are insulated from the case 1, thereby ensuring circuit reliability. The thickness of the insulating material 23 can be selected depending on a voltage to be used. In the present embodiment, the insulating material 23 employs silicon nitride whose thickness is approximately 0.64 mm. Depending on required pressure resistance or heat resistance, it is also possible to employ other ceramic materials or a resin sheet having an insulating property. As heat conductivity of the employed insulating material increases and the thickness is thinner, heat resistance can be minimized. In the insulating material 23, the heat radiating member 24 is arranged on a surface opposite to a side facing the metal circuit 22. In the present embodiment, only copper, silicon nitride, and solder are arranged between the semiconductor element 21 and the heat radiating member 24. Since all of these are thin members having high heat conductivity, it is possible to minimize the heat resistance between the semiconductor element 21 and the heat radiating member 24. In the present embodiment, the metal circuit 22 or the heat radiating member 24 employs copper, but it is also possible to employ aluminum or other metal materials. In a case of employing aluminum, the heat conductivity is lower than that of copper. Accordingly, whereas the heat resistance increases, there is a characteristic that the members are light in weight and are likely to be processed. The materials can be selectively used depending on use. The semiconductor element 21, the metal circuit 22, the insulating material 23, the heat radiating member 24, and the terminal 26 are sealed with the mold resin 25 except for a portion of the heat radiating member and the terminal 26. All of these are sealed with the mold resin 25, thereby preventing an electrical short circuit and ensuring pressure resistance. A thermal deformation difference between respective members which occurs during operation can be reduced, and strength reliability can be ensured.

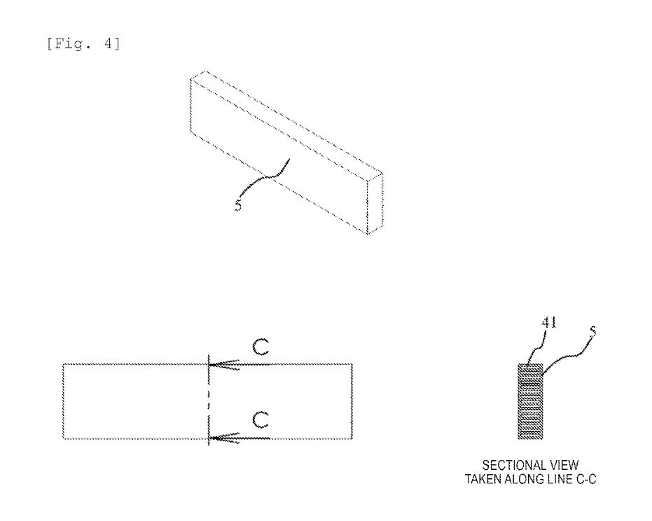

FIG. 4 illustrates an external view and a sectional view of the heat sink 5 configuring the power conversion device according to the first embodiment in the invention. The heat sink 5 has a role to cool the semiconductor member 27 while two surface serving as the main surface are in contact with the case. A fin is disposed in a direction substantially orthogonal to the main surface inside the heat sink 5, thereby forming a water passage 41. Although not illustrated, a water inlet port and a water outlet port of a coolant are disposed in both end portions in the longitudinal direction of the heat sink 5, thereby enabling the coolant to flow in and out. In the present embodiment, copper is employed as a material of the heat sink. Since copper having high heat conductivity is employed, heat resistance can be reduced. Depending on a type of cooling medium or required heat radiating performance, a different material such as aluminum can also be employed. In a case of employing aluminum, the heat conductivity is lower than that of copper. Accordingly, whereas the heat resistance increases, there is a characteristic that the heat sink is light in weight and is likely to be processed. The materials can be selectively used depending on use.

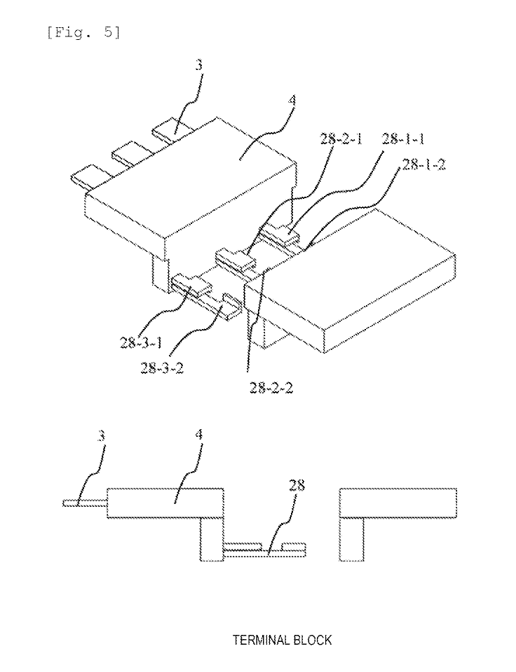

FIG. 5 illustrates an external view of the terminal block 4 configuring the power conversion device according to the first embodiment in the invention. In the present embodiment, the terminal block 4 is configured to include an epoxy resin. The copper-made external terminal 3 protrudes outside the terminal block 4, and the copper-made internal terminal 28 protrudes inside the terminal block 4. The external terminal 3 and the internal terminal 28 are coupled to each other inside the terminal block 4.

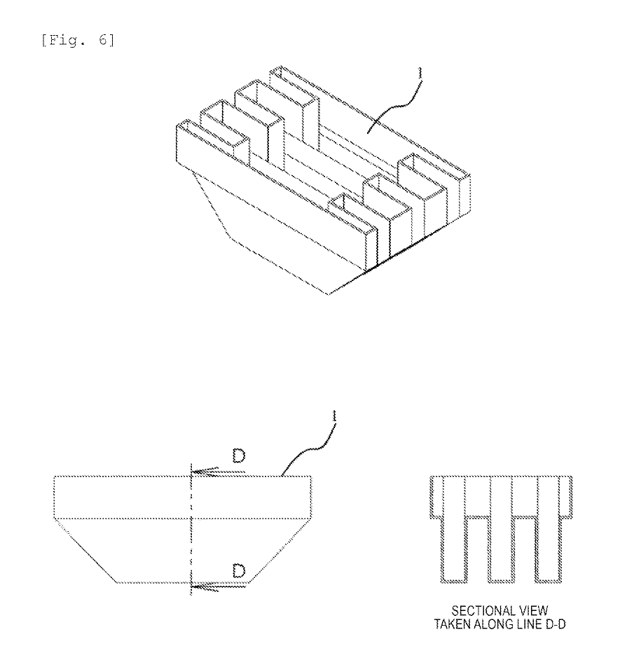

FIG. 6 illustrates an external view and a sectional view of the case 1 configuring the power conversion device according to the first embodiment in the invention. In the present embodiment, the case 1 is configured so that an aluminum plate whose thickness is 0.1 mm is subjected to bending process. Three recesses for inserting the semiconductor component 27 having the incorporated semiconductor element are disposed in the case 1, and the bending process is performed so that end portions are arranged on substantially the same plane. Accordingly, even if a liquid silicone gel is injected, the gel does not leak from the case 1, and the case 1 can be sealed with the silicone gel. Furthermore, a portion serving as a heat radiating path while facing the semiconductor component 27 having the incorporated semiconductor element or the heat sink 5 is planar, and has an effective shape in reducing heat resistance. In addition, the case 1 has a shape similar to a spring, and has extremely low rigidity in a direction perpendicular to the surface serving as the heat radiating path while facing the semiconductor component 27 or the heat sink 5, that is, in a direction where a component is pressurized in order to reduce contact heat resistance after the component is mounted. Therefore, when pressurized, the rigidity of the case 1 does not hinder the pressurizing. In the present embodiment, aluminum is employed for the material of the case 1, but it is also possible to employ other materials such as copper, or an alloy of aluminum and copper. In a case of employing copper for the case 1, heat conductivity is higher than that of aluminum. Accordingly, heat resistance can be further minimized. On the other hand, the rigidity becomes stronger than that of aluminum. In view of these characteristics, the material can be selected.

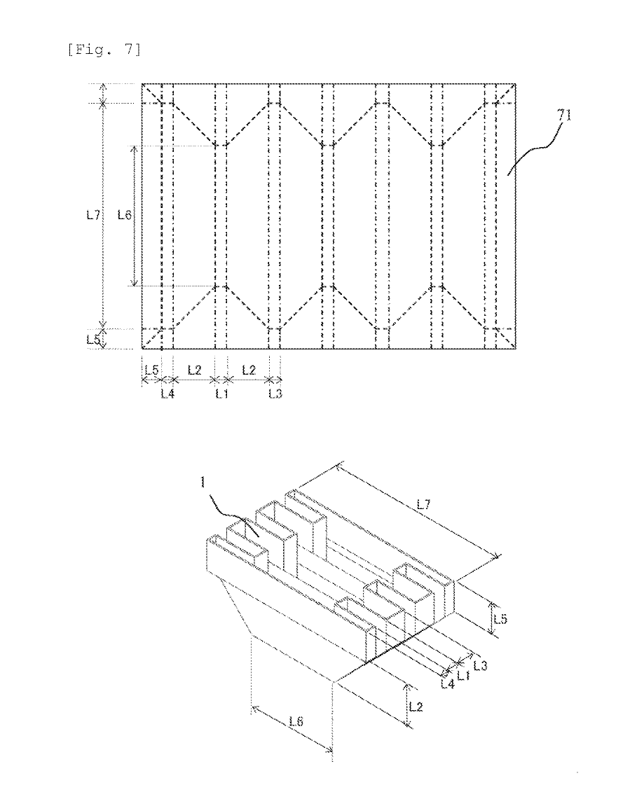

Referring to FIGS. 7 to 12, a method for manufacturing the power conversion device according to the first embodiment in the invention will be described.

First, referring to FIG. 7, a method for manufacturing the case 1 will be described. The case 1 is manufactured by performing a bending process on a substantially rectangular thin plate 71. The case 1 can be formed by performing valley bending on a dotted line portion illustrated in the drawing and performing mountain bending on a dotted chain line portion. In the present embodiment, an aluminum plate whose thickness is 0.1 mm is employed for the material of the case 1. Aluminum which is excellent in workability is employed so as to enable the bending process while breakage during the process is prevented. Accordingly, the completely manufactured case 1 has no hole from which the silicone gel leaks or no broken portion. In the thin plate 71, dimensions L1 to L7 after the bending process respectively represent as follows. L1 represents the width of the recess at the mounting position of the semiconductor component 27. L2 represents the depth of the recess at the mounting position of the semiconductor component 27. L3 represents the width at the installing position of the heat sink 5. L4 represents the width of an end portion of the case 1 at the installing position of the heat sink 5. L5 represents the height of an edge of the case 1. L6 represents the length of the recess at the mounting position of the semiconductor component 27. L7 represents the dimension of the case 1 in the longitudinal direction when the semiconductor component 27 is mounted. The dimension or bending portion of the thin plate 71 is determined depending on the dimension or the number of the semiconductor components 27 to be mounted or the heat sinks. In this manner, the case corresponding to any number of components or any component dimension can be manufactured.

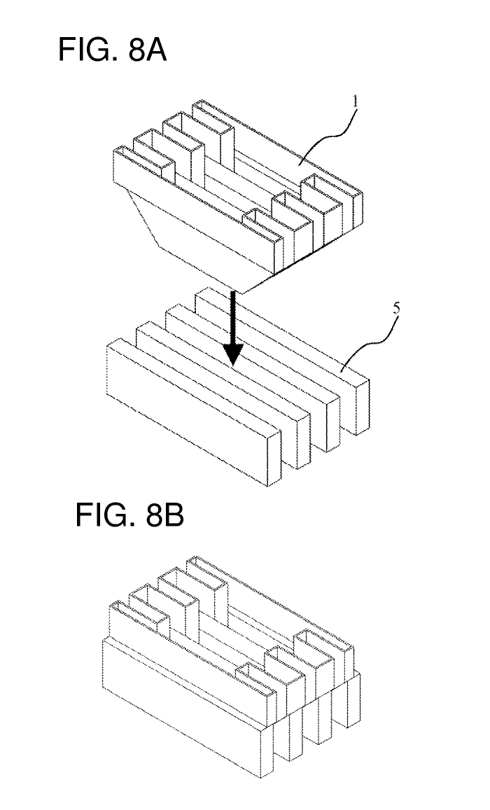

Next, as illustrated in FIG. 8a, four heat sinks 5 are arrayed side by side, and the case 1 is installed therebetween. Although not illustrated, each of the heat sinks 5 has a water inlet port and water outlet port. The ports of the respective heat sinks 5 are connected by pipes so that a coolant flows into all of the heat sinks 5. Depending on a connection method, the coolant can flow in series, or can flow in parallel into the respective heat sinks 5. If the case 1 is installed in the four heat sinks 5, a shape appears as illustrated in FIG. 8b.

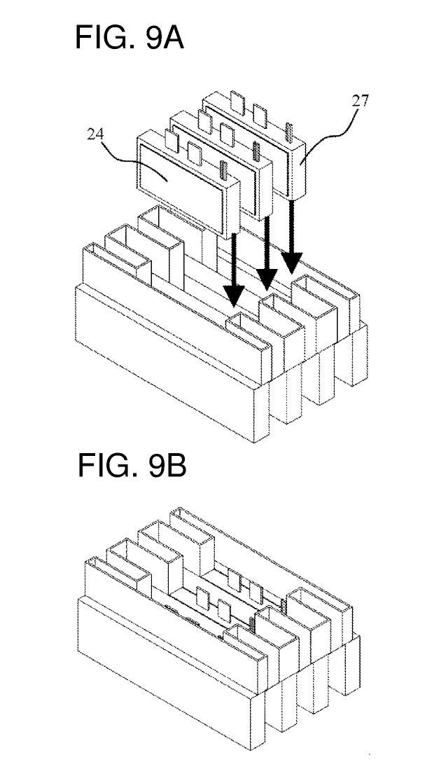

Next, as illustrated in FIG. 9a, the semiconductor components 27 having the incorporated semiconductor element are respectively installed in the three recesses of the case 1. In this case, a surface which serves as the main surface of the semiconductor component 27 and from which the heat radiating member 24 is exposed comes into contact with a surface of the case 1 which faces the main surface of the heat sink 5. In this manner, the heat sinks 5 can be respectively arranged on both surfaces of the semiconductor component 27. In the present embodiment, after the case 1 is installed in the upper portion of the heat sink 5, the semiconductor component 27 is installed in the recess of the case 1. However, after the semiconductor component 27 is installed in the recess of the case 1, the case 1 may be installed in the upper portion of the heat sink 5.

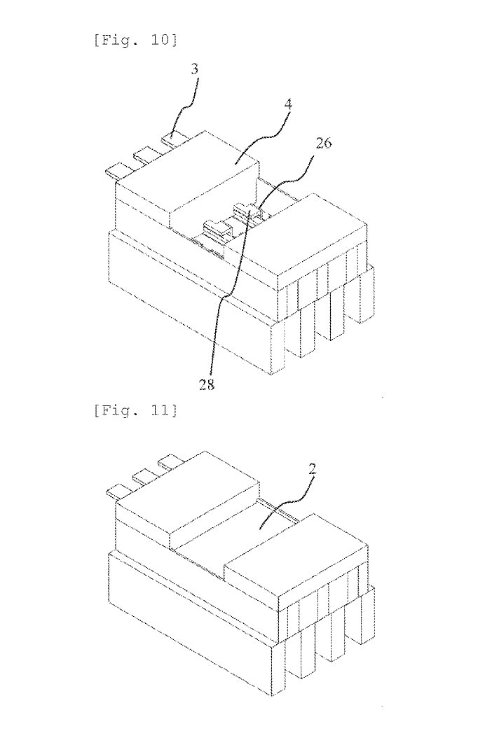

Next, as illustrated in FIG. 10, the terminal block 4 is arranged in the upper portion of the case 1. The terminal 26 of the semiconductor component 27 and the internal terminal 28 of the terminal block are joined to each other by means of welding.

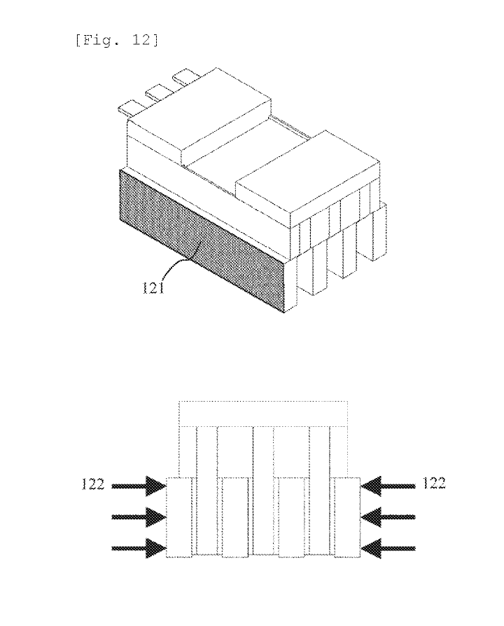

Next, as illustrated in FIG. 11, a liquid silicone gel prior to curing is injected as the sealing material 2 to a position on which the semiconductor component 27 is mounted inside the case 1. The liquid silicone gel is injected so that a liquid surface thereof is located higher than the terminal 26 of the conductor component 27 or the internal terminal 28 of the terminal block. In this manner, the semiconductor component 27, the terminal 26 of the conductor component 27, and the internal terminal 28 of the terminal block can be sealed. In this case, the case 1 is subjected to bending process so that end portions of one sheet of aluminum plate are arranged on substantially the same plane. Accordingly, if the liquid surface is located lower than the plane of the end portions, the liquid silicone gel does not leak. After the silicone gel is injected, the gel is cured, thereby completing the sealing.

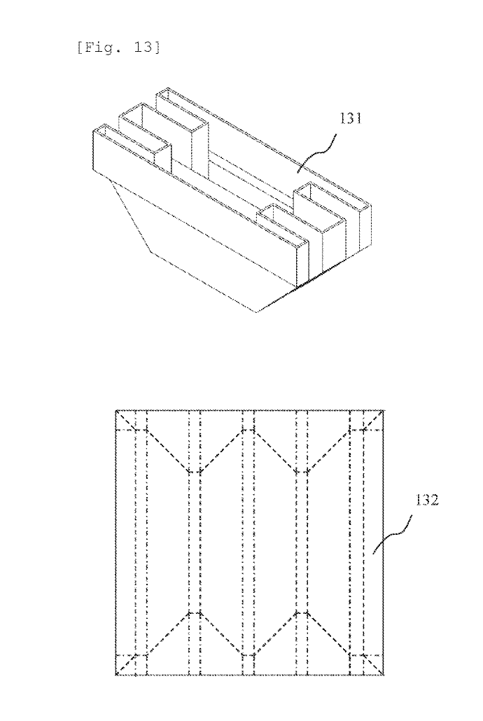

Finally, as illustrated in FIG. 12, a main surface located outside the two heat sinks 5 arranged in both ends is used as a pressurizing surface 121, and a pressurizing force 122 is applied to the pressurizing surface 121. In this manner, contact heat resistance is reduced between the semiconductor component 27 and the case 1 or between the case 1 and the heat sink 5. Although not illustrated, the present embodiment employs bolt fastening as a pressurizing method. Two plates in which a bolt hole is disposed outside the heat sink 5 are arranged, and are subjected to bolt fastening by using four bolts, thereby pressurizing the two plates.

Referring to FIGS. 1 to 12, in the power conversion device according to the first embodiment in the invention in which the structure and the manufacturing method have been described, the heat sinks 5 are arranged on both sides of all of the semiconductor components 27 having the semiconductor element. In this manner, it is possible to efficiently cool the semiconductor element 21 from both surfaces. In addition, the rigidity of the case 1 is weak in the pressurizing direction. Accordingly, in a case where heat resistance is reduced by pressurizing, the rigidity of the case 1 does not interfere with the pressurizing. Furthermore, through the bending process of the thin plate, a case shape is realized in which all sides configuring the outer shape of the thin plate are arranged on substantially the same plane. The semiconductor component 27 having the incorporated conductor device is arranged at the position serving as the recess. In this manner, the semiconductor component 27 having the incorporated semiconductor element 21 can be suitably sealed while the liquid silicone gel does not leak even if the silicone gel is injected for silicone gel sealing. For this reason, it is possible to provide the power conversion device which is excellent in cooling capacity or pressure resistance.

### Embodiment 2

FIG. 13 illustrates a case 131 and a development plan 132 thereof which configure a power conversion device according to a second embodiment in the invention. A point different from that in the case 1 employed in Embodiment 1 is as follows. Whereas the case 1 employed in Embodiment 1 has three recesses for arranging the semiconductor component 27 having the incorporated semiconductor element, the case 131 employed according to the present embodiment has two recesses. Therefore, compared to the development plan of the case 1 illustrated in FIG. 7, according to the development plan 132 of the case 131, the longitudinal dimension of the aluminum plate prior to the bending process is shorter, and fewer bending portions are provided. In this way, in the case used for the power conversion device according to the invention, the dimension or the bending portion of the aluminum plate to be used is selected. In this manner, the case can employ a shape corresponding to the number or the dimension of the semiconductor components 27 to be installed. This point is a major characteristic according to the invention.

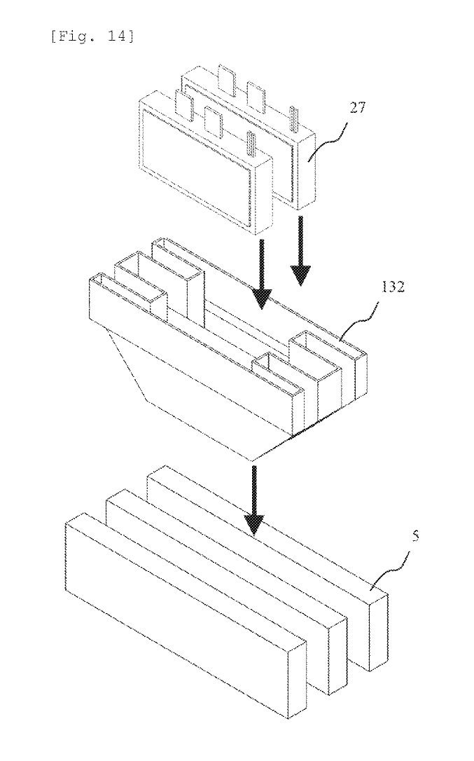

Referring to FIG. 14, a method for manufacturing the power conversion device according to the second embodiment in the invention will be described. Three heat sinks 5 are arrayed side by side, and the case 132 is installed therebetween. Although not illustrated, each of the heat sinks 5 has the water inlet port and the water outlet port similarly to Embodiment 1. The ports of the respective heat sinks 5 are connected by pipes so that a coolant flows into all of the heat sinks. Next, the semiconductor components 27 having the incorporated semiconductor element are respectively installed in two recesses of the case 132. In this case, the heat sink 5 is arranged so that a surface which serves as the main surface of the semiconductor component 27 and from which the heat radiating member 24 is exposed comes into contact with a surface of the case 1 which faces the main surface of the heat sink 5. In this manner, the heat sink 5 can be arranged on both surfaces of the semiconductor component 27. The subsequent manufacturing method is the same as that according to Embodiment 1. The terminal block 4 is arranged in the upper portion of the case 132. The terminal 26 of the semiconductor component 27 and the internal terminal 28 of the terminal block are joined to each other by means of welding. A liquid silicone gel prior to curing is injected into the case 132 as the sealing material 2, and is cured, thereby completely manufacturing the power conversion device.

According to Embodiment 1, the power conversion device internally includes the three semiconductor components 27. In contrast, according to the present embodiment, the power conversion device internally includes two semiconductor components 27. Conditions of a voltage or a current used for the power conversion device are different from those according to Embodiment 1. In this way, in the power conversion device according to the invention, the same semiconductor components 27 and heat sinks 5 are prepared, and the number of members to be used is freely changed. In this manner, it is possible to configure the power conversion device which is suitable for an intended use. Therefore, a wide lineup corresponding to various intended uses can be constructed using the same semiconductor components 27.

### Embodiment 3

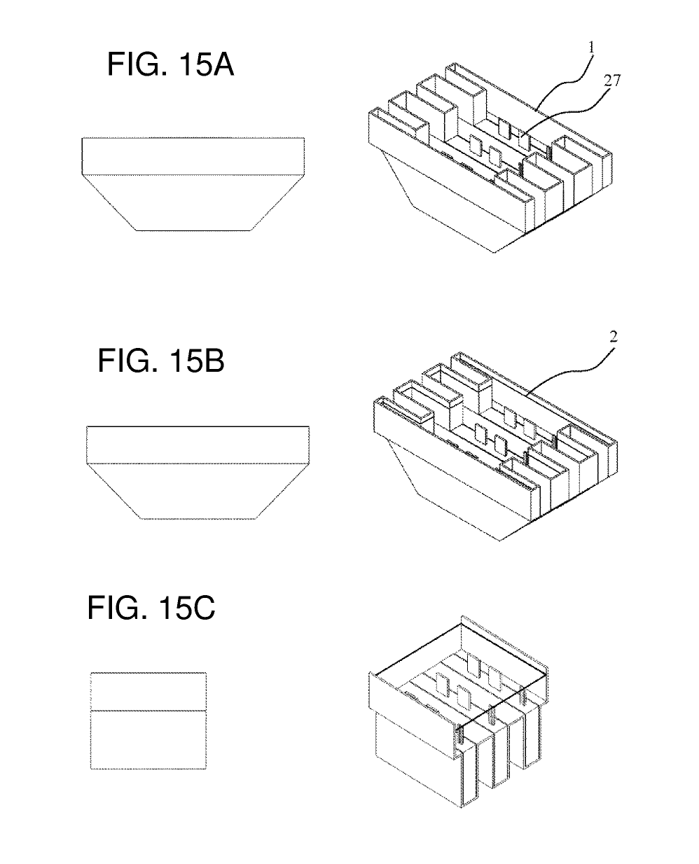

FIG. 15 is a view for describing a power conversion device according to a third embodiment in the invention. A different point between the present embodiment and the first embodiment is as follows. As illustrated in FIG. 15a, three semiconductor components 27 are mounted on the case 1. As illustrated in FIG. 15b, a terminal block (not illustrated) is installed and sealed with a silicone gel (contour is illustrated), and the gel is cured. Thereafter, as illustrated in FIG. 15c, a region of a trapezoidal shape in both longitudinal end portions of the case is cut off. The region of the trapezoidal shape in both longitudinal end portions of the case has a role to prevent leakage in a case where a liquid silicone gel is injected. However, after the silicone gel is cured, the leakage does not occur even if the region is cut off. Since the region is cut off, the case when in use can be miniaturized, and the heat sink can also be miniaturized. Accordingly, the overall power conversion device can be miniaturized. On the other hand, it becomes necessary to perform a process for cutting the case and the cured silicone gel. Therefore, depending on the purpose of miniaturization and process shortening, Embodiment 3 can be adopted separately from Embodiment 1.

### Embodiment 4

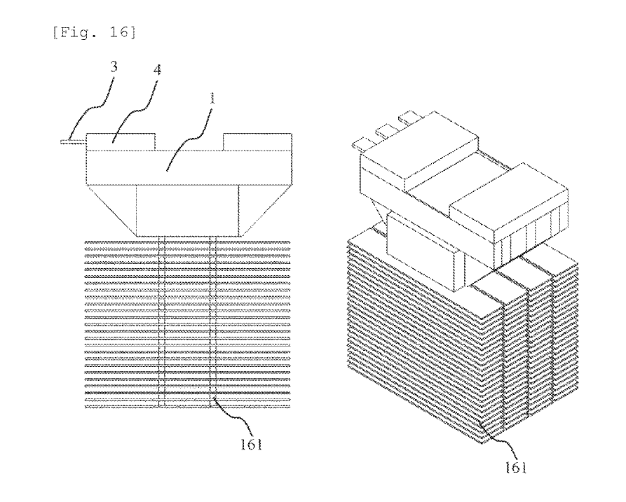

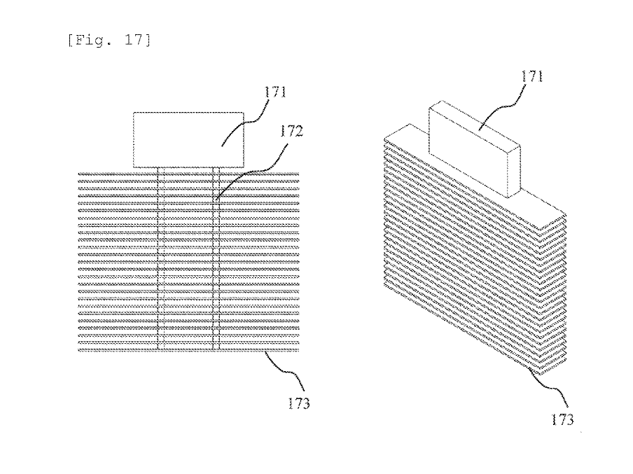

FIG. 16 illustrates an external view of a power conversion device according to a fourth embodiment in the invention. A point different from that according to the first embodiment is that cooling is performed using a heat pipe 161 instead of the water cooling heat sink 5. FIG. 17 illustrates the heat pipe 161 employed in the present embodiment. A pipe portion 172 internally having a liquid protrudes from a contact portion 171 between the heat pipe and the case, and a cooling fin 173 is connected to the protruding portion. In the power conversion device illustrated in FIG. 16, four heat pipes 161 and the contact portion 171 between the heat pipe and the case are arranged on both sides of the semiconductor component 27 via the case 1, and cool the semiconductor component 27 from the both surfaces. In the drawing, the heat pipe 161 is arranged below the power conversion device, but the heat pipe is arranged above the power conversion device during operation. As a result, the liquid inside the pipe portion 172 is arranged in the vicinity of the semiconductor component 27, and is vaporized due to heat generation of the semiconductor component 27. The vapor moves to the vicinity of the cooling fin 173, and is cooled and liquefied. The liquid moves again to the vicinity of the semiconductor component 27. This cycle is repeated, thereby cooling the semiconductor component 27. In the present embodiment, the four heat pipes 161 are employed, but these heat pipes 161 may be connected at a position of the cooling fin 173. In this case, whereas handling such as mounting work is facilitated, rigidity inevitably increases. Therefore, it is necessary to pay attention to a shape of the cooling fin 173 so as not to hinder pressurizing.

In the power conversion device according to the invention, the semiconductor component, wires, and a cooling portion are separated from each other by the case 1. Accordingly, a major characteristic is that the present embodiment employs a different cooling method without changing the semiconductor component or the wires. The present embodiment employs a cooling method using the heat pipe. However, depending on required cooling capacity, the present embodiment can also employ other cooling methods such as an air cooling method. Even in a case where any cooling method is employed, the semiconductor component 27 can be cooled from both surfaces.

### Embodiment 5

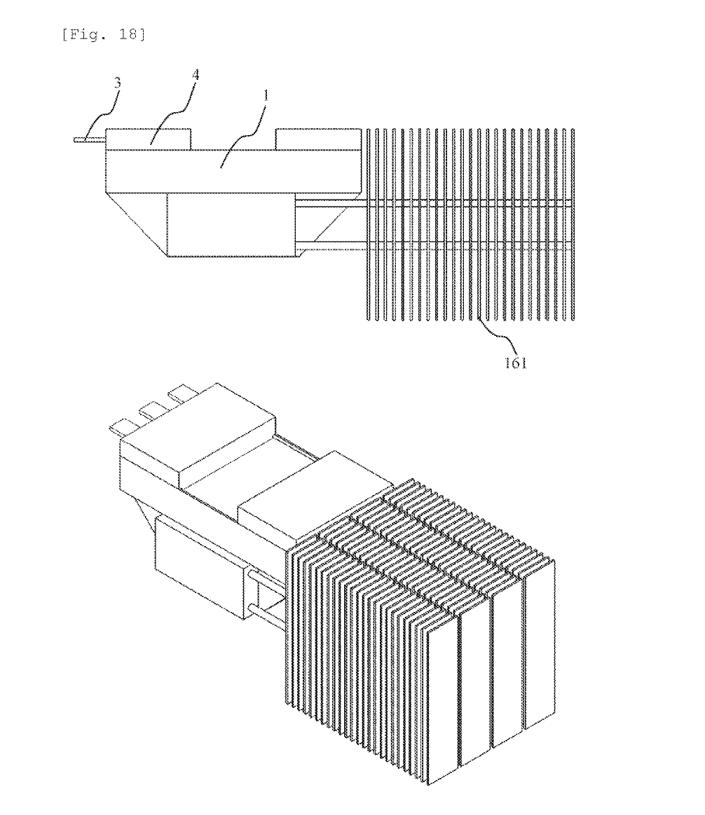

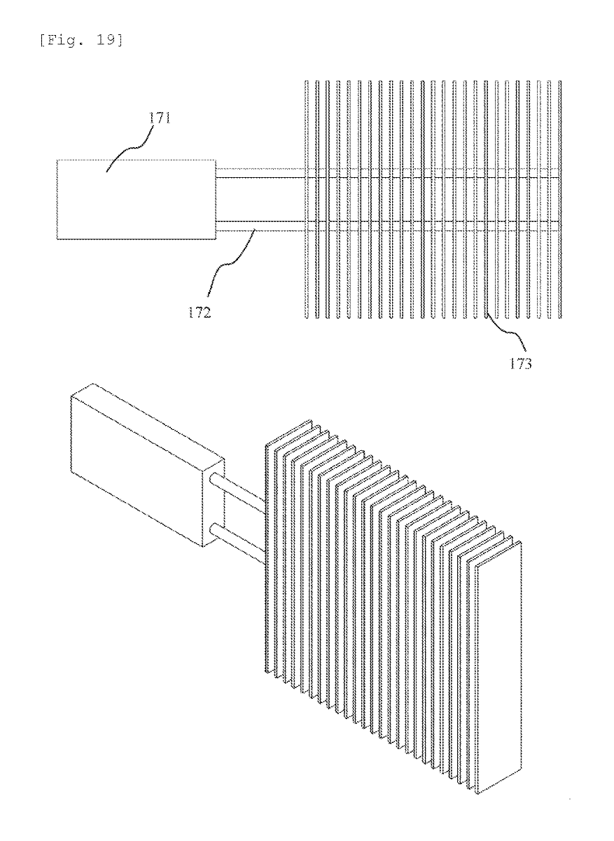

FIG. 18 illustrates an external view of a power conversion device according to a fifth embodiment in the invention. A point that cooling is performed using the heat pipe 161 is the same as that according to the fourth embodiment. However, a point different from that according to the fourth embodiment is that the heat pipe 161 is disposed in the horizontal direction of the power conversion device. According to the fourth embodiment, the heat pipe 161 is arranged in the downward direction of the power conversion device. When operated, the heat pipe needs to be arranged on the upper side. Accordingly, the overall device needs to be largely rotated. According to the present embodiment, if the overall device is slightly rotated, the slight rotation provides a function as the heat pipe. Furthermore, if the pipe portion 172 of the heat pipe 161 employs a “V-shape”, the power conversion device does not need to be rotated. The pipe portion tip of the heat pipe 161 is arranged above the base portion. This can provide the function as the heat pipe. The reason is as follows. The power conversion device according to the invention has a characteristic that at a position where the contact portion 171 of the heat pipe 161 between the heat pipe and the case is brought into contact with the case 1, the case 1 is guided not only in the downward direction but also in the lateral direction, and the pipe 172 of the heat pipe 161 is guided not only in the downward direction but also in the lateral direction. In this way, the power conversion device according to the invention has a characteristic that a shape of cooling components to be mounted can be very freely selected. In a case of employing the present embodiment, as illustrated in FIG. 19, it is necessary to prevent the cooling fin 173 and the case 1 from coming into contact with each other by securing a distance from the contact portion 171 between the heat pipe and the case to the cooling fin 173 so as to be farther than that in the fourth embodiment. Depending on a shape of an installation space for installing the power conversion device or an air flow, these embodiments can be selected.

### Embodiment 6

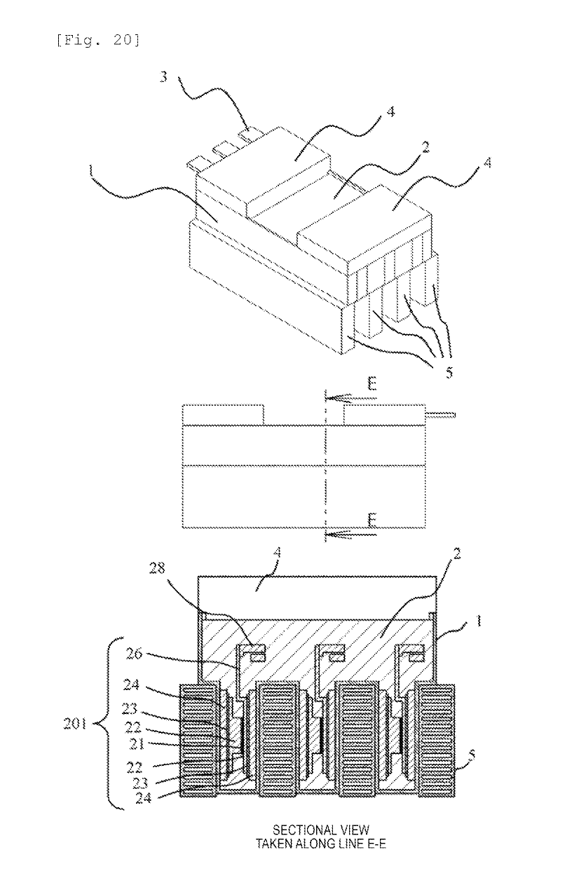

FIG. 20 illustrates an external view and a sectional view of a power conversion device according to a sixth embodiment in the invention. The external view is the same as that according to Embodiment 1. A point different from that according to Embodiment 1 is as follows. In the sectional view, the semiconductor component 27 having the incorporated semiconductor element has no mold resin 25, and the entire sealing is performed using only the sealing material 2 which is the silicone gel. In the present embodiment, when the semiconductor component 27 having the incorporated semiconductor element is manufactured, resin molding is not required. Accordingly, the manufacturing process can be simplified. In addition, as much as the mold resin is omitted, the outer dimension of the semiconductor component 27 can be minimized. Therefore, the overall power conversion device is effectively miniaturized. In the present embodiment, the outer dimension of the insulating material 23 can become larger than that of the metal circuit 22. In this manner, even if the mold resin 25 is not provided, when the semiconductor component 27 is installed in the case 1, the case 1 and the metal circuit 22 do not come into contact with each other, and electrical short circuit can be prevented. Furthermore, after the silicone gel is injected, pressure resistance can be sufficiently ensured. However, the semiconductor element 21 or the metal circuit 22 is not sealed with the mold resin 25. Accordingly, it is necessary to pay attention to reducing thermal stress caused by a thermal deformation difference of each member due to temperature rising during operation. As a method for reducing the thermal deformation difference of each member, it is an effective way to use molybdenum or tungsten which is a material whose linear expansion coefficient is less different from that of the semiconductor element 21, for at least a portion of the metal circuit 22. In addition, in order to reduce the thermal stress, it is also an effective way to use carbon or a composite material containing carbon for a portion of the metal circuit 22.

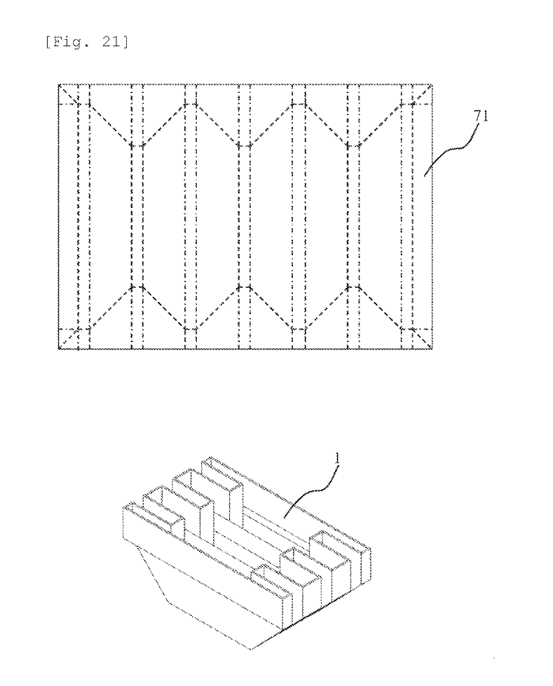

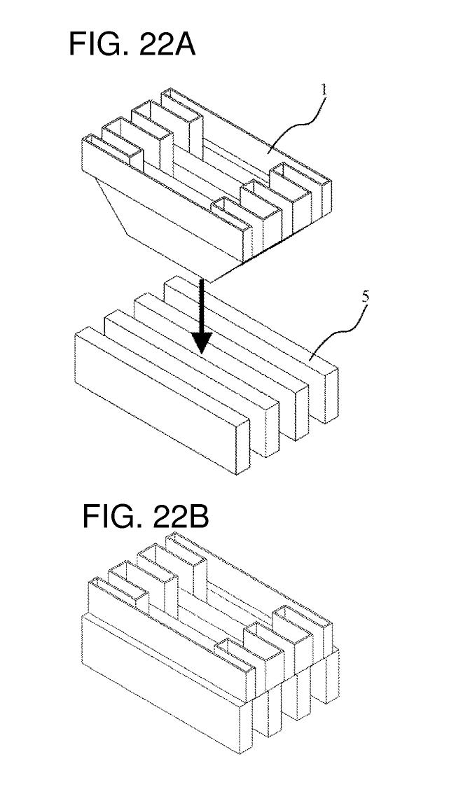

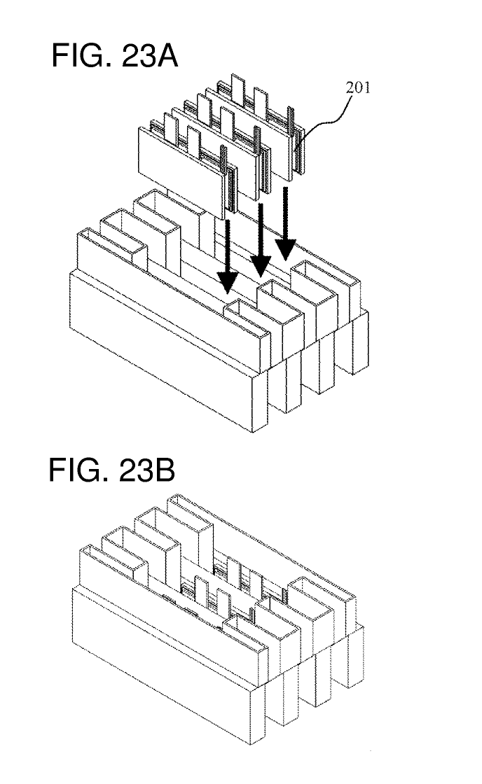

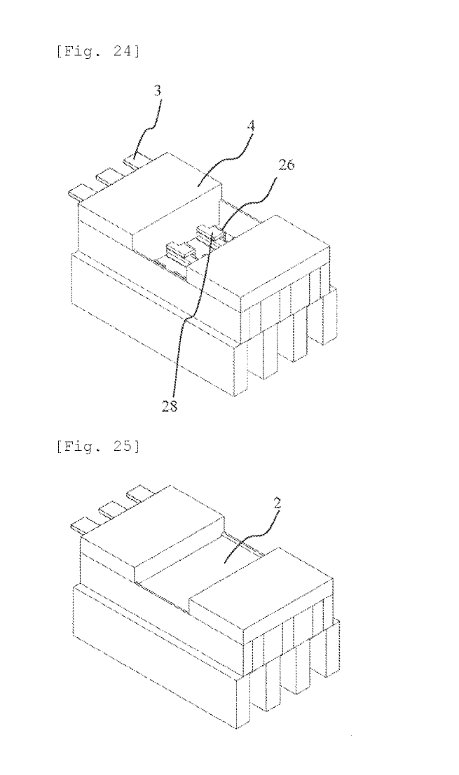

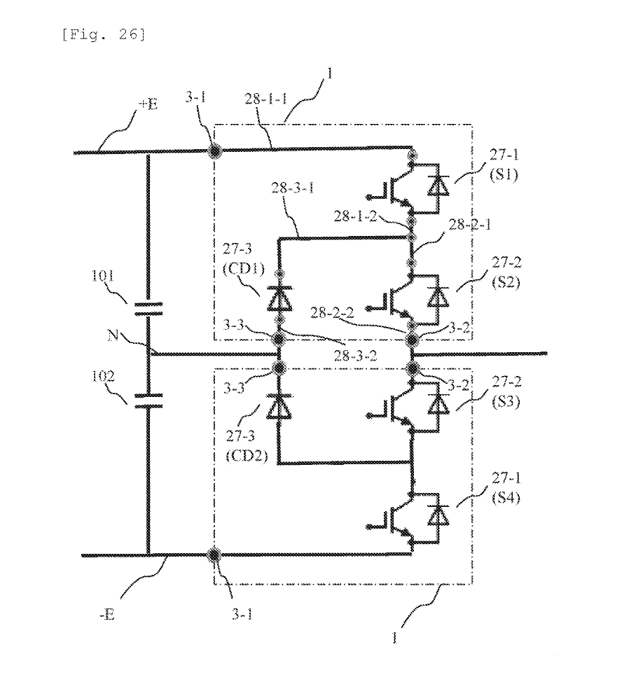

Referring to FIGS. 21 to 25, a method for manufacturing the power conversion device according to the sixth embodiment in the invention will be described. The method for manufacturing the case 1 illustrated in FIG. 21 is the same as that according to Embodiment 1. However, since the outer dimension of the semiconductor component 27 becomes smaller, the case 1 can be miniaturized. Next, as illustrated in FIG. 22, the case 1 is installed in the heat sink 5. Since the outer dimension of the semiconductor component 27 becomes smaller, the heat sink 5 can also be miniaturized. Next, as illustrated in FIG. 23, the semiconductor component 27 is installed in the case 1. In this case, the semiconductor component 27 is not molded, and the metal circuit 22 or the semiconductor element 21 is exposed. Accordingly, it is necessary to pay attention to handling. Next, as illustrated in FIG. 24, the terminal block 4 is installed in the upper portion of the case 1, and the terminals 26 and 28 are connected to each other. Next, a liquid silicone gel is injected into the case 1, and the gel is cured. In this manner, all of the semiconductor element 21, the metal circuit 22, and the terminal 26 are sealed. Although not illustrated, the heat sink 5 is finally pressurized, thereby completely manufacturing the power conversion device.

As described with reference to the above embodiments, an object can be achieved as follows. A substantially rectangular thin plate is subjected to mountain bending and valley bending so as to form a shape having as many recesses as the number of the mounted semiconductor components having the incorporated semiconductor element. Concurrently, a lateral side in the direction orthogonal to the above-described bending direction is bent so as to dispose the case in which all edges configuring an outer shape of the thin plate are arranged on substantially the same plane. The semiconductor component having the incorporated semiconductor element is arranged at a position serving as the recess of the case. The cooling devices are arranged so as to interpose the semiconductor component having the incorporated semiconductor element via the case. The semiconductor component having the incorporated semiconductor element is sealed with a silicone gel. In addition, preferably, the case is configured to include metal which has high heat conductivity. More preferably, the case is configured to include aluminum, copper, or an alloy whose principal components are both of these.

In the cooling device, multiple independent cooling modules are arranged on both sides of the semiconductor component having the incorporated semiconductor element, and the respective cooling modules are connected at a low rigid connection portion in the pressurizing direction. Furthermore, the terminal block support member is arranged in a side portion of the semiconductor component having the incorporated semiconductor element so as to support the terminal block. In this case, the thickness of the terminal block support member is set to be smaller than the thickness of the semiconductor component having the incorporated semiconductor element.

According to this configuration, the semiconductor component having the incorporated semiconductor element and the cooling device can be alternately arranged. Accordingly, the semiconductor element can be efficiently cooled from both surfaces. In addition, the rigidity of the case decreases in the direction where the semiconductor component having the incorporated semiconductor element and the cooling device are alternately arranged. Accordingly, in a case where heat resistance is reduced by the pressurizing a portion between the semiconductor component having the incorporated semiconductor element and the cooling device, the rigidity of the case does not interfere with the pressurizing. Furthermore, through the bending process of the thin plate, a case shape is realized in which all of the edges are arranged on substantially the same plane. The semiconductor component having the incorporated conductor device is arranged at the position serving as the recess. Accordingly, the semiconductor component having the incorporated semiconductor element can be suitably sealed while the sealing material such as the liquid silicone gel does not leak even if the silicone gel is injected. For this reason, it is possible to provide the power conversion device which is excellent in cooling capacity or pressure resistance. Furthermore, it is possible to prevent the cooling device or the terminal block support member from hindering the pressurizing of the semiconductor component having the incorporated semiconductor element and the cooling device. Therefore, suitable pressurizing can be realized.

Hitherto, the invention has been described in detail with reference to the embodiments. However, as a matter of course, the invention is not limited to the above-described embodiments, and can be modified in various ways within the scope not departing from the gist of the invention.

### REFERENCE SIGNS LIST

1 CASE
2 SEALING MATERIAL
3 EXTERNAL TERMINAL
4 TERMINAL BLOCK
5 HEAT SINK
21 SEMICONDUCTOR ELEMENT
22 METAL CIRCUIT
23 INSULATING MATERIAL
24 HEAT RADIATING MEMBER MOLD RESIN
26, 26a, 26b TERMINAL OF SEMICONDUCTOR COMPONENT HAVING INCORPORATED SEMICONDUCTOR ELEMENT
27 SEMICONDUCTOR COMPONENT HAVING INCORPORATED SEMICONDUCTOR ELEMENT
28 INTERNAL TERMINAL
41 WATER PASSAGE
71 THIN PLATE PRIOR TO CASE BENDING PROCESS
L1 BENDING DIMENSION OF THIN PLATE
L2 BENDING DIMENSION OF THIN PLATE
L3 BENDING DIMENSION OF THIN PLATE
L4 BENDING DIMENSION OF THIN PLATE
L5 BENDING DIMENSION OF THIN PLATE
L6 BENDING DIMENSION OF THIN PLATE
L7 BENDING DIMENSION OF THIN PLATE
121 PRESSURIZING SURFACE
122 PRESSURIZING FORCE
131 CASE IN EMBODIMENT 2
132 CASE DEVELOPMENT PLAN IN EMBODIMENT 2
161 HEAT PIPE
171 CONTACT PORTION BETWEEN HEAT PIPE AND CASE
172 PIPE PORTION OF HEAT PIPE
173 COOLING FIN PORTION OF HEAT PIPE

1. A power-module device configured to cause a cooling member to cool a semiconductor component from both surface sides by alternately arranging the semiconductor component and the cooling member,
wherein a plurality of the semiconductor components are provided,
wherein the semiconductor component includes a semiconductor element and a terminal connected to the semiconductor element,
wherein at least a portion of the semiconductor element performs a switching operation,
wherein the semiconductor component has an integral case in which a plate material is molded so as to isolate the semiconductor component and the cooling member from each other, and
wherein the case has an extension portion for sealing the terminal with a sealing material, and further has a cooling medium path which connects the cooling members to each other, or a cooling fin which is thermally connected to the cooling member.

2. The power-module device according to claim 1,
wherein the case is molded by performing a bending process on a thin plate.

3. The power-module device according to claim 2,
wherein the case is made of aluminum or copper as a principal component.

4. The power-module device according to claim 1,
wherein at least any one of the semiconductor components has a heat radiating member arranged on both main surfaces of the semiconductor element.

5. The power-module device according to claim 1,
wherein the number of the cooling members is one more than the number of the semiconductor components.

6. The power-module device according to claim 1,
wherein the cooling member includes a heat pipe.

7. The power-module device according to claim 1,
wherein the semiconductor component is arranged in a recessed portion formed in the case.

8. A power conversion device configured to cause a cooling member to cool a semiconductor component from both surface sides by alternately arranging the semiconductor component and the cooling member,
wherein a plurality of the semiconductor components are provided,
wherein the semiconductor component includes a semiconductor element and a terminal connected to the semiconductor element,
wherein at least a portion of the semiconductor element performs a switching operation,
wherein the semiconductor component has an integral case in which a plate material is molded so as to isolate the semiconductor component and the cooling member from each other,
wherein the case has an extension portion for sealing the terminal with a sealing material, and further has a cooling medium path which connects the cooling members to each other, or a cooling fin which is thermally connected to the cooling member, and
wherein the switching operation is controlled so as to perform power conversion.
